(19) United States
(12) Patent Application Publication
(10) Pub. No.: US 2026/0371743 A1
(43) Pub. Date: Nov. 19, 2026

(54) ELECTROSTATIC DISCHARGE PROTECTION STRUCTURE AND MANUFACTURING METHOD THEREOF

(71) Applicant: Winbond Electronics Corp., Taichung City (TW)

(72) Inventors: Shu Yuan Hsu, Taichung City (TW); Chao-Lung Wang, Taichung City (TW)

(73) Assignee: Winbond Electronics Corp., Taichung City (TW)

(21) Appl. No.: 19/645,330

(22) Filed: Apr. 13, 2026

(30) Foreign Application Priority Data
May 15, 2025 (TW) 114118253

(51) Int. Cl. H10D 89/60; H10D 62/13; H10D 64/62

(52) U.S. Cl. CPC H10D 89/811; H10D 62/151; H10D 64/62

(57) ABSTRACT

An electrostatic discharge protection structure including a substrate, a plurality of gate structures, a drain region, a source region and a metal silicide layer. The substrate has a plurality of trenches. The plurality of gate structures are disposed on the substrate, wherein the plurality of trenches are disposed between adjacent gate structures. The drain region is disposed in the substrate and is located at one side of one of the plurality of gate structures, wherein the drain region surrounds the plurality of trenches. The source region is disposed in the substrate and is located at the other side of one of the plurality of gate structures. The metal silicide layer is disposed on the substrate and defines a non-metal-silicide region. The non-metal-silicide region is a region where no metal silicide layer is provided, and the non-metal-silicide region overlaps with the plurality of trenches in a top-view direction of the substrate.

### CROSS-REFERENCE TO RELATED APPLICATION

This application claims the priority benefit of Taiwan application serial no. 114118253, filed on May 15, 2025. The entirety of the above-mentioned patent application is hereby incorporated by reference herein and made a part of this specification.

### BACKGROUND

### Technical Field

The disclosure relates to an electrostatic discharge protection structure and a manufacturing method thereof, and in particular relates to an electrostatic discharge protection structure having multiple trenches formed in a drain region and a manufacturing method thereof.

### Description of Related Art

In order to reduce damage to integrated circuits in semiconductor devices (such as memory devices) caused by electrostatic discharge (ESD), ESD protection structures are typically provided in the semiconductor devices. In ESD protection structures of prior art, the resistance is increased by increasing the area of non-metal-silicide region in the drain area, thereby enhancing the anti-static performance of the ESD protection structures. However, this approach results in an increase in the layout area of the ESD protection structure.

### SUMMARY

An electrostatic discharge protection structure which can reduce the layout area while having relatively good anti-static performance is provided in the disclosure.

An electrostatic discharge protection structure disclosed in the disclosure includes a substrate, multiple gate structures, a drain region, a source region and a metal silicide layer. The substrate has multiple trenches. The gate structures are disposed on the substrate, in which the trenches are disposed between adjacent gate structures. The drain region is disposed in the substrate and is located at one side of one of the gate structures, in which the drain region surrounds the trenches. The source region is disposed in the substrate and is located at another side of one of the gate structures. The metal silicide layer is disposed on the substrate and defines a non-metal-silicide region. The non-metal-silicide region is a region where no metal silicide layer is provided, and the non-metal-silicide region overlaps with the trenches in a top-view direction of the substrate.

A manufacturing method of an electrostatic discharge protection structure is provided in the disclosure. The electrostatic discharge protection structure manufactured by the method can reduce the layout area while having relatively good anti-static performance.

The manufacturing method of the electrostatic discharge protection structure disclosed in the disclosure includes the following process. A substrate is provided, in which multiple gate structures are disposed on the substrate, a first heavily doped region and a source region are disposed in the substrate, the first heavily doped region is located on one side of one of the gate structures, and the source region is located on one side of one of the gate structures. Multiple trenches are formed in the substrate, in which the trenches are located between adjacent gate structures, and a depth of the trenches is greater than a depth of the first heavily doped region. A second heavily doped region is formed in the substrate, in which the second heavily doped region is connected to the first heavily doped region to form a drain region, and the drain region surrounds the trenches. A metal silicide layer is formed on the substrate to define a non-metal-silicide region, in which the non-metal-silicide region is a region where no metal silicide layer is provided, and the non-metal-silicide region overlaps with the trenches in a top-view direction of the substrate.

Based on the above, in the electrostatic discharge protection structure and the manufacturing method thereof disclosed in the disclosure, the path of the electrostatic discharge current in the drain region can be increased by disposing multiple trenches, thereby enabling the electrostatic discharge protection structure disclosed in the disclosure to reduce the layout area while having relatively good anti-static performance.

In order to make the aforementioned features and advantages of the disclosure comprehensible, embodiments accompanied with drawings are described in detail below.

### BRIEF DESCRIPTION OF THE DRAWINGS

FIG. 1 is a process schematic diagram of a manufacturing method of an electrostatic discharge protection structure of an embodiment of the disclosure.

FIG. 2A is a top schematic diagram of an electrostatic discharge protection structure of an embodiment of the disclosure.

FIG. 2B is a cross-sectional schematic diagram of an electrostatic discharge protection structure of an embodiment of the disclosure.

### DETAILED DESCRIPTION OF DISCLOSED EMBODIMENTS

The following examples are described in detail with the accompanying drawings, but the provided examples are not intended to limit the scope of the disclosure. In addition, the drawings are for illustrative purposes only and are not drawn in full scale. In order to facilitate understanding, the same elements in the following description are described with the same symbols.

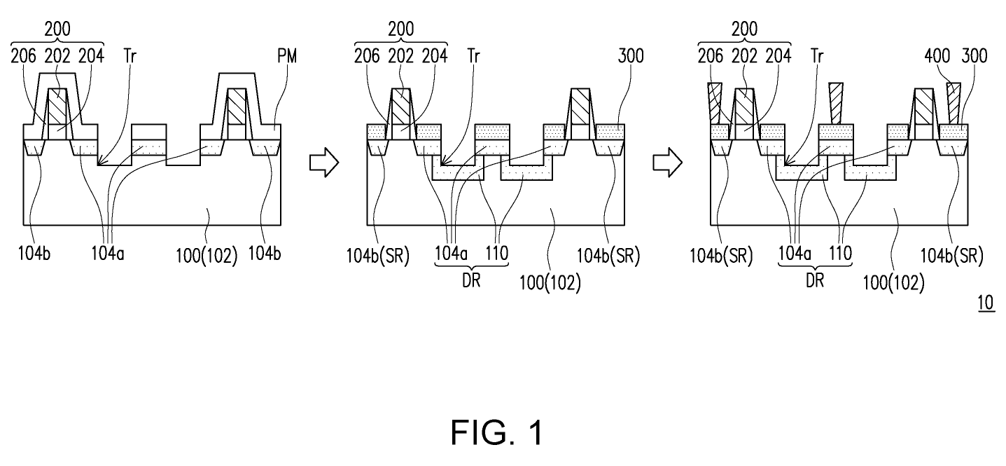

Referring to FIG. 1, FIG. 1 shows a method for forming an electrostatic discharge protection structure 10, which may include the following steps.

Step (1): a substrate 100 is provided. The substrate 100 may be a suitable semiconductor material. For example, the material of the substrate 100 may include silicon (Si), germanium (Ge), gallium arsenide (GaAs), silicon germanium (SiGe), other suitable materials or a combination of the above materials. In some embodiments, the substrate 100 may include a semiconductor substrate or a semiconductor on insulator (SOI) substrate.

Multiple gate structures 200 are formed on the substrate 100, in which the gate structures 200 can be formed on the substrate 100 by performing a common semiconductor process. One of the gate structures 200 may include a gate 202, a gate dielectric layer 204 and a spacer 206. The material of the gate 202 may include polycrystalline silicon (poly Si), titanium (Ti), aluminum (Al), tungsten (W), gold (Au), or a combination thereof. The gate dielectric layer 204 is disposed between the gate 202 and the substrate 100, and the material of the gate dielectric layer 204 may include silicon oxide (SiO₂), silicon oxynitride (SiON), silicon nitride (SiN) or other suitable dielectric materials. The spacer 206 is disposed on the sidewalls of the gate 202 and the gate dielectric layer 204, and the material of the spacer 206 may also include silicon oxide, silicon oxynitride, silicon nitride or other suitable dielectric materials.

The substrate 100 includes a well region 102 having a first conductivity type, in which the well region 102 may be formed in the substrate 100 by performing an ion implantation process.

The substrate 100 further includes a heavily doped region 104 having a second conductivity type, in which the heavily doped region 104 may be formed in the well region 102 by performing an ion implantation process, and the gate structures 200 may serve as masks, but the disclosure is not limited thereto. In some embodiments, the first conductivity type may be P-type, and the second conductivity type may be N-type. In this embodiment, the heavily doped region 104 includes a heavily doped region 104a and a heavily doped region 104b. The heavily doped region 104a and the heavily doped region 104b are respectively located at opposite sides of the gate structure 200.

Step (2): multiple trenches Tr are formed in the substrate 100, in which the trenches Tr are located between adjacent gate structures 200. The method for forming the trenches Tr may include performing the following steps, but the disclosure is not limited thereto.

First, a mask layer PM is formed on the substrate 100, in which the mask layer PM covers the gate structure 200 and exposes a portion of the substrate 100. In some embodiments, the mask layer PM may be formed on the substrate 100 by performing a deposition process and a photolithography and etching process. The material of the mask layer PM may include tetraethylsiloxane, silicon oxide or other suitable materials.

Afterwards, an etching process is performed on the exposed substrate 100 using the mask layer PM to form multiple trenches Tr between adjacent gate structures 200. In some embodiments, the depth of the trenches Tr is greater than the depth of the heavily doped region 104a. In other words, the bottom portions of the trenches Tr may expose the well region 102.

Step (3): a heavily doped region 110 having the second conductivity type is formed in the substrate 100. The heavily doped region 110 may be formed in the well region 102 by performing an ion implantation process, and the mask layer PM may serve as a mask. In some embodiments, the heavily doped region 110 may surround the bottom portion of the trench Tr.

In this embodiment, the heavily doped region 110 and the heavily doped region 104 may have similar doping concentrations. From another perspective, the heavily doped region 104a and the heavily doped region 110 located between adjacent gate structures 200 and connected to each other can serve as the drain region DR, and a drain region DR surrounds the trench Tr. In addition, the heavily doped region 104b may serve as a source region SR.

After forming the doped region 110, the mask layer PM is removed.

Step (4): a metal silicide layer 300 is formed on the substrate 100. The method for forming the metal silicide layer 300 may include performing the following steps, but the disclosure is not limited thereto.

First, a mask layer (not shown) is formed on the substrate 100, in which the mask layer exposes a portion of the substrate 100 and is at least formed in the trench Tr of the substrate 100. For the method for forming the mask layer and the material of the mask layer, reference may be made to the description of the mask layer PM in the above embodiment, and are not repeated herein.

Afterwards, a silicidation process is performed on the exposed substrate 100 to form a metal silicide layer 300. In some embodiments, the silicidation process may include performing the following steps, but the disclosure is not limited thereto. Step (A): a suitable metal layer (not shown) deposited on the substrate 100, in which a portion of the metal layer contacts the substrate 100 exposed by the mask layer. Step (B): an annealing process is performed on the metal layer so that the metal layer in contact with the silicon in the substrate 100 reacts to form a silicide. Step (C): the unreacted portion of the metal layer is removed to form a metal silicide layer 300. In some embodiments, the material of the metal silicide layer 300 includes cobalt silicon (CoSi).

After the metal silicide layer 300 is formed, the mask layer is removed.

Step (5): multiple terminals 400 are formed on the substrate 100, in which the terminals 400 are electrically connected to a corresponding metal silicide layer 300.

At this point, the manufacturing process of the electrostatic discharge protection structure 10 is completed. Although the manufacturing method of the electrostatic discharge protection structure 10 of this embodiment is described by taking the above method as an example, the manufacturing method of the electrostatic discharge protection structure disclosed in the disclosure is not limited thereto.

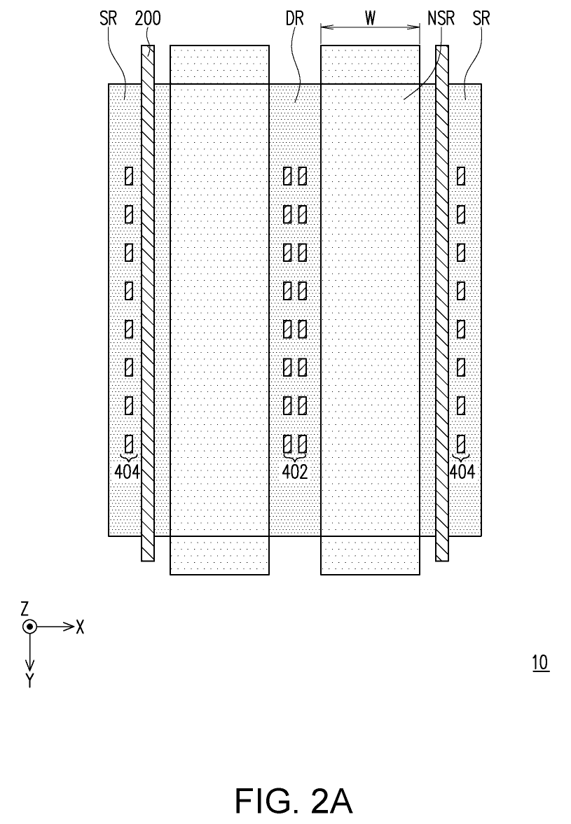

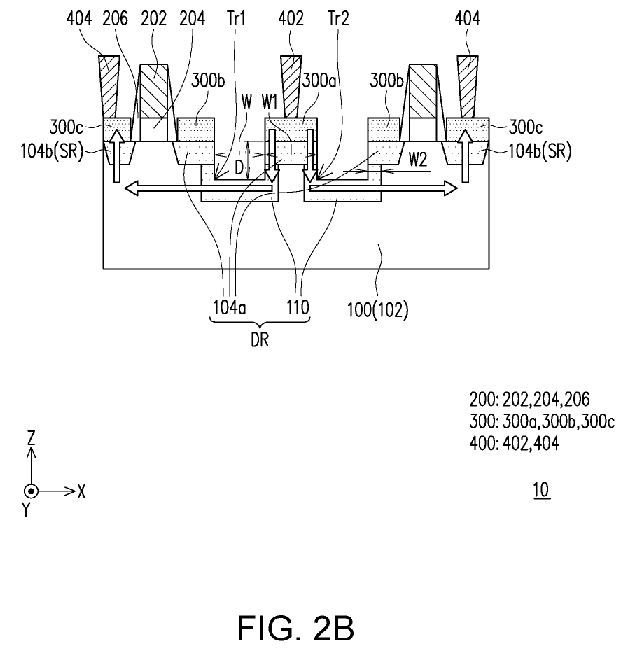

The structure of the electrostatic discharge protection structure 10 of this embodiment is briefly introduced below with reference to FIGS. 2A and 2B . The embodiments of FIGS. 2A and 2B may respectively use the reference numerals and a part of the contents of the embodiment of FIG. 1, and the same or similar reference numerals are used to denote the same or similar elements, and the description of the same technical content is omitted.

Referring to FIGS. 2A and 2B , the electrostatic discharge protection structure 10 of this embodiment includes a substrate 100, multiple gate structures 200, a metal silicide layer 300 and multiple terminals 400.

The substrate 100 may be, for example, doped to have a conductivity type. The substrate 100 includes a well region 102, a heavily doped region 104 and a heavily doped region 110. The well region 102 has a first conductivity type, and the heavily doped region 104 and the heavily doped region 110 have a second conductivity type, in which the first conductivity type may be P-type, and the second conductivity type may be N-type. The heavily doped region 104 and the heavily doped region 110 may have similar doping concentrations. In this embodiment, the well region 102 has a doping concentration of 1E15 to 1E20 cm⁻³, and the heavily doped region 104 and the heavily doped region 110 have a doping concentration of 1E18 to 1E21 cm⁻³. From another perspective, the heavily doped region 104 may include a heavily doped region 104a and a heavily doped region 104b. The heavily doped region 104a and the heavily doped region 104b are respectively located at opposite sides of the gate structure 200. In addition, the heavily doped region 104a and the heavily doped region 110 located between adjacent gate structures 200 and connected to each other may serve as a drain region DR, and the heavily doped region 104b may serve as a source region SR.

In addition, the substrate 100 has multiple trenches Tr. In this embodiment, the substrate 100 has a trench Tr1 and a trench Tr2. In this embodiment, the trench Tr1 and the trench Tr2 have a depth of 0.1 microns to 3 microns, and the depth of the trench Tr1 and the trench Tr2 may be 1 to 30 times the thickness of the heavily doped region 104b. The trench Tr1 and the trench Tr2 are disposed between adjacent gate structures 200. In this embodiment, the trench Tr1 and the trench Tr2 are respectively surrounded by the heavily doped region 104a and the heavily doped region 110. Specifically, the heavily doped region 110 surrounds the bottom portion of the trench Tr1 and the bottom portion of the trench Tr2, and surrounds a portion of the sidewall of the trench Tr1 and a portion of the sidewall of the trench Tr2. The heavily doped region 110 surrounds the lower half of the sidewall of the trench Tr1 and the lower half of the sidewall of the trench Tr2. The heavily doped region 104a surrounds another portion of the sidewall of the trench Tr1 and another portion of the sidewall of the trench Tr2. The heavily doped region 104a surrounds the upper half of the sidewall of the trench Tr1 and the upper half of the sidewall of the trench Tr2. In this embodiment, the heavily doped region 104a surrounding the upper half of the sidewalls of the trench Tr1 and the trench Tr2 has a width W1, and the heavily doped region 110 surrounding the lower half of the sidewalls of the trench Tr1 and the trench Tr2 has a width W2, in which the width W1 is greater than the width W2.

Multiple gate structures 200 are disposed on the substrate 100. One of the gate structures 200 may include a gate 202, a gate dielectric layer 204 and a spacer 206. The gate dielectric layer 204 is disposed between the gate 202 and the substrate 100, and the spacer 206 is disposed on the sidewalls of the gate 202 and the gate dielectric layer 204. In this embodiment, the gate structures 200 extend in a direction Y. In some embodiments, the drain region DR may be disposed on one side of the gate structure 200, and the source region SR may be disposed on the other side of the gate structure 200.

The metal silicide layer 300 is disposed on the substrate 100. In some embodiments, the metal silicide layer 300 includes a metal silicide layer 300a, a metal silicide layer 300b, and a metal silicide layer 300c. The metal silicide layer 300a and the metal silicide layer 300b are disposed on the substrate 100 between adjacent gate structures 200. In detail, the metal silicide layer 300a is disposed on the substrate 100 between the trench Tr1 and the trench Tr2. The metal silicide layer 300b is disposed on the substrate 100 between the trench Tr1 and the gate structure 200, and is disposed on the substrate 100 between the trench Tr2 and the gate structure 200. In this embodiment, the heavily doped region 104a is disposed below the metal silicide layer 300b. The metal silicide layer 300c and the metal silicide layer 300b are respectively disposed on the substrate 100 at opposite sides of the gate structure 200.

From another perspective, the metal silicide layer 300 may define a non-metal-silicide region NSR. In detail, the non-metal-silicide region NSR is a region on the substrate 100 where no metal silicide layer 300 is provided. In this embodiment, the non-metal-silicide region NSR includes a trench Tr1 and a trench Tr2 of the substrate 100. In other words, the non-metal-silicide region NSR overlaps the trench Tr1 and the trench Tr2 in the top-view direction (direction Z) of the substrate. By defining the non-metal-silicide region NSR, the resistance of the drain region can be increased, thereby enhancing the anti-static performance of the electrostatic discharge protection structure 10 of this embodiment.

Multiple terminals 400 are disposed on the substrate 100 and electrically connected to a corresponding metal silicide layer 300. In this embodiment, the terminals 400 may include an input/output terminal 402 and a power terminal 404. The input/output terminal 402 is electrically connected to the metal silicide layer 300a, and the power terminal 404 is electrically connected to the metal silicide layer 300c. The input/output terminal 402 may be, for example, coupled to a peripheral circuit (not shown) of a memory device (not shown). For example, the input/output terminal 402 may be electrically connected to an input/output buffer (not shown), but the disclosure is not limited thereto. The power terminal 404 may be, for example, grounded to receive a ground voltage, but the disclosure is not limited thereto.

In this embodiment, by disposing the trench Tr1 and the trench Tr2, the layout area of the electrostatic discharge protection structure 10 can be reduced while having relatively good anti-static performance. Specifically, when the input/output terminal 402 receives an excessively high voltage pulse, the configuration of the trench Tr1 and the trench Tr2 can relatively increase the path of the electrostatic discharge current in the drain region DR (e.g., the path indicated by the arrow in FIG. 2B). Therefore, when the electrostatic discharge protection structure 10 of this embodiment is applied to a memory device (not shown), the electrostatic discharge protection structure can maintain relatively good anti-static performance in a limited space of the memory device. Furthermore, in this embodiment, by disposing the trench Tr1 and the trench Tr2, the electrostatic discharge current can flow through deeper portions of the substrate 100, thereby reducing the occurrence of unevenly distributed current density, so that the electrostatic discharge protection structure 10 of this embodiment can have better anti-static performance.

Furthermore, the non-metal-silicide region of the prior art has a width (e.g., 1.5 microns) in the direction X, which is approximately the path of the electrostatic discharge current. In contrast, the path of the electrostatic discharge current of the electrostatic discharge protection structure 10 of this embodiment may be substantially composed of the width W (e.g., 0.7 microns) of the non-metal-silicide region NSR in the direction X and twice the depth D (e.g., 0.4 microns) in the direction Z. Based on this, compared with the electrostatic discharge protection structure in the prior art, the electrostatic discharge protection structure 10 of this embodiment can have relatively good anti-static performance with a relatively small layout area.

To sum up, in the electrostatic discharge protection structure and the manufacturing method thereof of this embodiment, the path of the electrostatic discharge current in the drain region can be increased by disposing multiple trenches, thereby reducing the layout area of the electrostatic discharge protection structure of this embodiment while having relatively good anti-static performance. Therefore, when the electrostatic discharge protection structure of this embodiment is applied to semiconductor devices such as memory devices, the electrostatic discharge protection structure can maintain relatively good anti-static performance in a limited space. Furthermore, the electrostatic discharge current can flow through deeper portions of the substrate of the electrostatic discharge protection structure, thereby reducing the occurrence of unevenly distributed current density, so that the electrostatic discharge protection structure of this embodiment can have better anti-static performance.

What is claimed is:

1. An electrostatic discharge protection structure, comprising:
a substrate, having a plurality of trenches;
a plurality of gate structures, disposed on the substrate, wherein the trenches are disposed between adjacent gate structures;
a drain region, disposed in the substrate and located at one side of one of the gate structures, wherein the drain region surrounds the trenches
a source region, disposed in the substrate and located at another side of one of the gate structures; and
a metal silicide layer, disposed on the substrate and defining a non-metal-silicide region,
wherein the non-metal-silicide region is a region where no metal silicide layer is provided, and the non-metal-silicide region overlaps with the trenches in a top-view direction of the substrate.

2. The electrostatic discharge protection structure according to claim 1, further comprising:
a plurality of terminals, disposed on the substrate and electrically connected to a corresponding metal silicide layer.

3. The electrostatic discharge protection structure according to claim 2, wherein the terminals comprise an input/output terminal and a power supply terminal.

4. The electrostatic discharge protection structure according to claim 3, wherein the metal silicide layer comprises:
a first metal silicide layer, disposed between adjacent trenches; and
a second metal silicide layer, disposed on the another side of one of the gate structures,
wherein the input/output terminal is electrically connected to the first metal silicide layer, and the power terminal is electrically connected to the second metal silicide layer.

5. The electrostatic discharge protection structure according to claim 1, wherein the drain region comprises:
a first heavily doped region, surrounding an upper half of a sidewall of the trenches; and
a second heavily doped region, surrounding a bottom portion of the trenches and surrounding a lower half of the sidewall of the trenches.

6. The electrostatic discharge protection structure according to claim 5, wherein the first heavily doped region surrounding the upper half has a first width, the second heavily doped region surrounding the lower half has a second width, and the first width is greater than the second width.

7. The electrostatic discharge protection structure according to claim 5, wherein the metal silicide layer comprises:
a third metal silicide layer, disposed on the substrate between one of the trenches and the gate structures, wherein the first heavily doped region is disposed below the third metal silicide layer.

8. The electrostatic discharge protection structure according to claim 1, wherein the substrate further comprises a well region, and the drain region and the source region are located in the well region.

9. The electrostatic discharge protection structure according to claim 8, wherein the well region has a first conductivity type, and the drain region and the source region have a second conductivity type.

10. The electrostatic discharge protection structure according to claim 1, wherein the metal silicide layer comprises:
a first metal silicide layer and a second metal silicide layer, disposed on the substrate between the adjacent gate structures.

11. The electrostatic discharge protection structure according to claim 10, wherein the first metal silicide layer is disposed on the substrate between a first trench and a second trench of the plurality of trenches.

12. The electrostatic discharge protection structure according to claim 10, wherein the second metal silicide layer is disposed on the substrate between the first trench and the gate structure, and is disposed on the substrate between the second trench and the gate structure.

13. The electrostatic discharge protection structure according to claim 10, wherein the metal silicide layer further comprises:
a third metal silicide layer, wherein the third metal silicide layer and the second metal silicide layer are respectively disposed on the substrate at opposite sides of the gate structure.

14. The electrostatic discharge protection structure according to claim 13, wherein the drain region comprises a first heavily doped region disposed below the second metal silicide layer, and the source region comprises a second heavily doped region disposed below the third metal silicide layer.

15. A manufacturing method of an electrostatic discharge protection structure, comprising:
providing a substrate, wherein a plurality of gate structures are disposed on the substrate, a first heavily doped region and a source region are disposed in the substrate, the first heavily doped region is located on one side of one of the gate structures, and the source region is located on one side of one of the gate structures;
forming a plurality of trenches in the substrate, wherein the trenches are located between adjacent gate structures, and a depth of the trenches is greater than a depth of the first heavily doped region;
forming a second heavily doped region in the substrate, wherein the second heavily doped region is connected to the first heavily doped region to form a drain region, and the drain region surrounds the trenches; and
forming a metal silicide layer on the substrate to define a non-metal-silicide region,
wherein the non-metal-silicide region is a region where no metal silicide layer is provided, and the non-metal-silicide region overlaps with the trenches in a top-view direction of the substrate.

16. The manufacturing method of the electrostatic discharge protection structure according to claim 15, further comprising:
forming a plurality of terminals on the substrate, wherein the terminals are electrically connected to a corresponding metal silicide layer.

17. The manufacturing method of the electrostatic discharge protection structure according to claim 15, wherein forming the trenches in the substrate comprises:
forming a mask layer on the substrate, wherein the mask layer exposes a portion of the substrate; and
performing an etching process on the exposed substrate using the mask layer.

18. The manufacturing method of the electrostatic discharge protection structure according to claim 15, wherein the second heavily doped region is formed by performing an ion implantation process.

19. The manufacturing method of the electrostatic discharge protection structure according to claim 15, wherein forming the metal silicide layer on the substrate comprises:
forming a mask layer on the substrate, wherein the mask layer exposes a portion of the substrate and the mask layer is formed in the trenches of the substrate; and
performing a silicidation process on the exposed substrate using the mask layer.

20. The manufacturing method of the electrostatic discharge protection structure according to claim 15, wherein the substrate further comprises a well region, and the drain region and the source region are located in the well region, wherein the well region has a first conductivity type, and the drain region and the source region have a second conductivity type.
